(19) United States
(12) Patent Application Publication
(10) Pub. No.: US 2004/0104834 A1
(43) Pub. Date: Jun. 3, 2004

(54) Data slicer

(75) Inventor: Kyoko Enami, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: RENESAS TECHNOLOGY CORP., Tokyo (JP); MITSUBISHI ELECTRIC SYSTEM LSI DESIGN CORPORATION, Itami-shi (JP)

(21) Appl. No.: 10/436,251

(22) Filed: May 13, 2003

(30) Foreign Application Priority Data
Nov. 28, 2002 (JP) 2002-345182

(51) Int. Cl. H03M 1/12

(52) U.S. Cl. 341/155

(57) ABSTRACT

In determining a level of a digital signal to be either “0” or “1” (0/1-determination), erroneous determination occurring under influences of a noise superimposed on an input signal is prevented. A data slicer (100) receives a video signal digitized by an A/D converter circuit (1), as an input signal. A 0/1-determining circuit (2) determines a level of the input signal relative to a predetermined reference level, and outputs a digital signal (A) based on a result of the determination. A control part (3) outputs a control signal (B) based on the digital signal (A). The predetermined reference level used in the 0/1-determination is switched between two levels by a first selector circuit (4), based on the control signal (B).

### BACKGROUND OF THE INVENTION

1. Field of the Invention

The present invention relates to a technique for generation of a digital signal.

2. Description of the Background Art

Data in a form of a specific analog signal (for example, teletext data or data expressed in the European teletext standard) which is superimposed on a video signal is digitized by an analog-to-digital converter circuit (A/D converter circuit). Then, it is necessary to repeatedly make determination of an level of an output signal supplied from the A/D converter circuit, i.e., repeatedly determine whether the level of the output signal is positive or negative relative to a predetermined reference level, to convert the output signal into a digital signal composed of rectangular pulses each representing either a value “0” or a value “1”, whichever is in accordance with each result of the determination. Such digital signal can be described as a pulse signal obtained by slicing the output signal supplied from the A/D converter circuit using the predetermined reference level. An apparatus for carrying out processes associated with “slicing” is called a “data slicer”. If a noise is superimposed on the output signal supplied from the A/D converter circuit during slicing of the output signal, it is probably that an error occurs in determining a level of the output signal to be either positive or negative relative to the predetermined reference level (determining the level of the output signal to be “1” or “0”), to increase a bit error rate of the digital signal resulted from the slicing.

Conventional techniques for suppressing influences of a noise in slicing a predetermined portion of a video signal includes a technique in which a search to obtain an optimum value of a slice level (a reference level used for slicing the predetermined portion of the video signal) is automatically conducted, to adjust the slice level, which is described in Japanese Patent Application Laid-Open No. 7-203394, for example.

For the foregoing reasons, suppression of a noise in slicing a signal using a predetermined reference level to obtain a digital signal is one of the most significant tasks for reducing a bit error rate of the digital signal to be obtained.

### SUMMARY OF THE INVENTION

It is an object of the present invention to prevent erroneous determination from occurring in a data slicer for slicing an input signal using a predetermined reference level, under influences of a noise superimposed on the input signal.

According to the present invention, a data slicer includes a determining circuit, and a control part and a first selector circuit. The determining circuit makes determination of a level of an input signal relative to a predetermined reference level and outputting a digital signal in accordance with a result of the determination. The control part outputs a control signal based on the digital signal. The first selector circuit changes the predetermined reference level based on the control signal.

It is possible to reduce errors in determining the level of the input signal to be either “0” or “1” (0/1-determination) which are likely to occur under influences of a noise superimposed on the input signal. For example, by causing the reference level to change with a hysteresis, it is possible to suppress influences of the noise. Also, by varying an operation for generating the control signal of the control part in accordance with a type of the input signal, an amplitude of a noise superimposed on the input signal, or the like, it is also possible to suppress influences of a specific noise.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view illustrating a structure of a data slicer according to the present invention.

FIG. 2 is a view illustrating a structure of a control part of the data slicer according to a first preferred embodiment.

FIG. 3 is a view for illustrating an operation of the data slicer according to the first preferred embodiment.

FIG. 4 is a view for illustrating a problem possibly caused in the first preferred embodiment.

FIG. 5 is a view illustrating a structure of the control part of the data slicer according to a second preferred embodiment.

FIG. 6 is a view for illustrating an operation of the data slicer according to the second preferred embodiment.

FIG. 7 is a view for illustrating an operation of the data slicer according to a third preferred embodiment.

FIG. 8 is a view illustrating an exemplary structure of the control part of the data slicer according to the third preferred embodiment.

FIG. 9 is a view illustrating a structure of a calculation circuit included in the control part of the data slicer according to the third preferred embodiment.

FIG. 10 is a timing chart for illustrating an operation of the control part of the data slicer according to the third preferred embodiment.

FIG. 11 is a view illustrating a structure of the control part of the data slicer according to a fourth preferred embodiment.

### DESCRIPTION OF THE PREFERRED EMBODIMENTS

First Preferred Embodiment

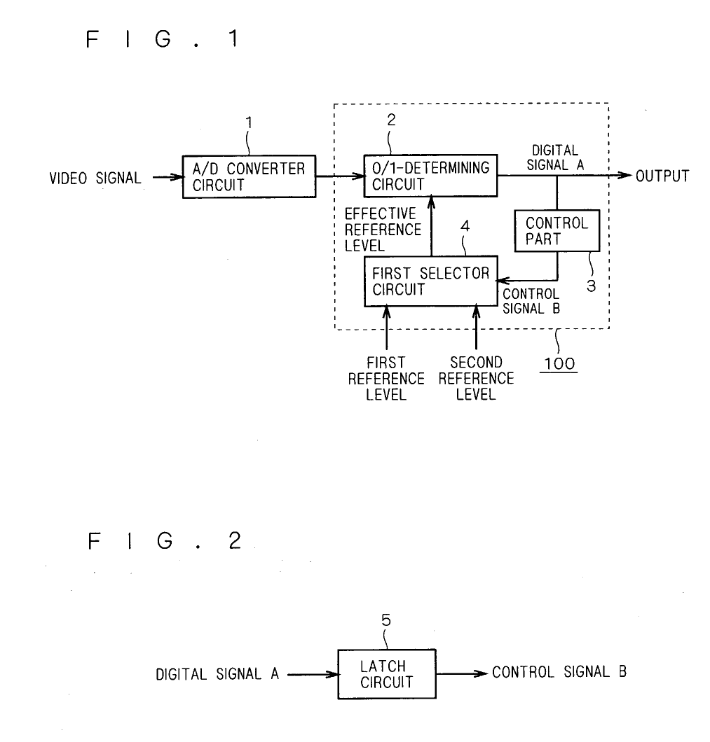

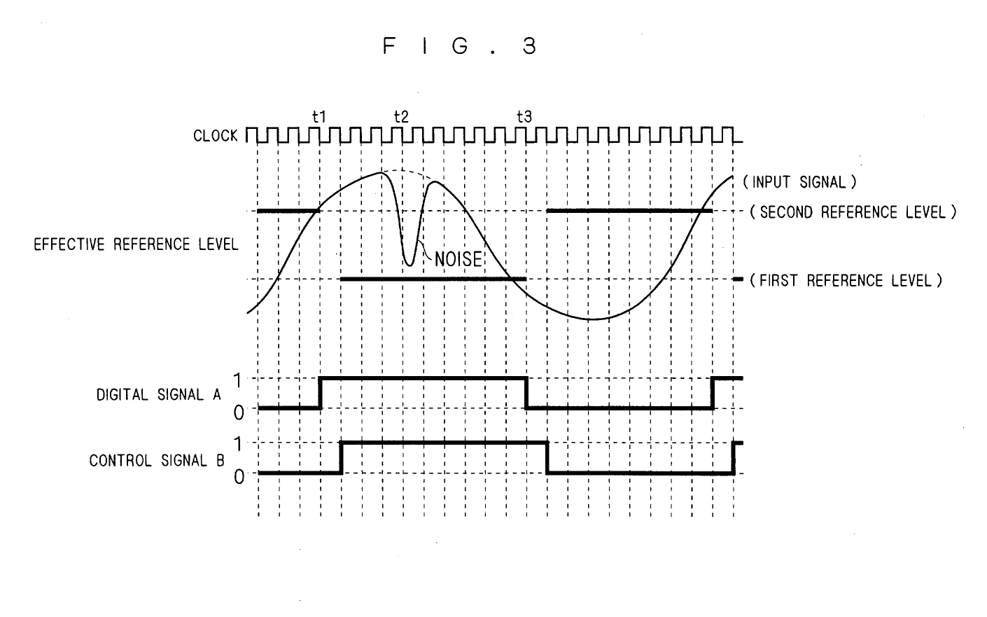

FIG. 1 is a view illustrating a structure of a data slicer 100 according to the present invention. FIG. 2 is a view illustrating a structure of a control part 3 included in the data slicer 100 according to a first preferred embodiment of the present invention.

The data slicer 100 receives a video signal which is digitized by an A/D converter circuit 1, as an input signal. The input signal is first input to a 0/1-determining circuit 2 which repeatedly determines a level of the input signal relative to a predetermined reference level (so that the level of the input signal is repeatedly determined to be either “0” or “1”). Then, a pulse signal composed of rectangular pulses each representing either a value “0” or a value “1” in accordance with each level of the input signal as determined is output from the 0/1-determining circuit 2, as a digital signal A. Specifically, in the digital signal A, each of the pulses occurring in a period during which the level of the input signal is higher than the predetermined reference level represents a value “1”, while each of the pulses occurring in a period during which the level of the input signal is lower than the predetermined reference level represents a value “0”. The reference level used in repeatedly determining the level of the input signal to be either “0” or “1” (“0/1-determination”) is switched between two levels by a first selector circuit 4 which will be described later. Additionally, the data slicer 100 also receives reference clocks at a predetermined frequency, and operates in accordance with operation timings which are synchronized with the reference clocks while coinciding with respective falling edges of the reference clocks, although illustration therefor is omitted in the drawings.

The digital signal A is output to an outside, and is also input to the control part 3. Upon receipt of the digital signal A, the control part 3 outputs a control signal B obtained based on the digital signal A. As illustrated in FIG. 2, according to the first preferred embodiment, the control part 3 includes a single latch circuit 5. A value of the digital signal A provided at a preceding one of the operation timings which occurs in a period of a preceding clock (i.e., a period between a rising edge and a subsequent rising edge of the clock, which will be hereinafter referred to as a “clock period”) is latched in the latch circuit 5, and is output from the control part 3, as the control signal B.

The first selector circuit 4 switches the reference level used in the 0/1-determination carried out in the 0/1-determining circuit 2 (“effective reference level”) between a first reference level and a second reference level, based on the control signal B supplied from the control part 3. Respective values of the first and second reference levels may be externally input to the first selector circuit 4 as illustrated in FIG. 1, or alternatively, the first selector circuit 4 may be configured so as to store respective values of the first and second reference levels.

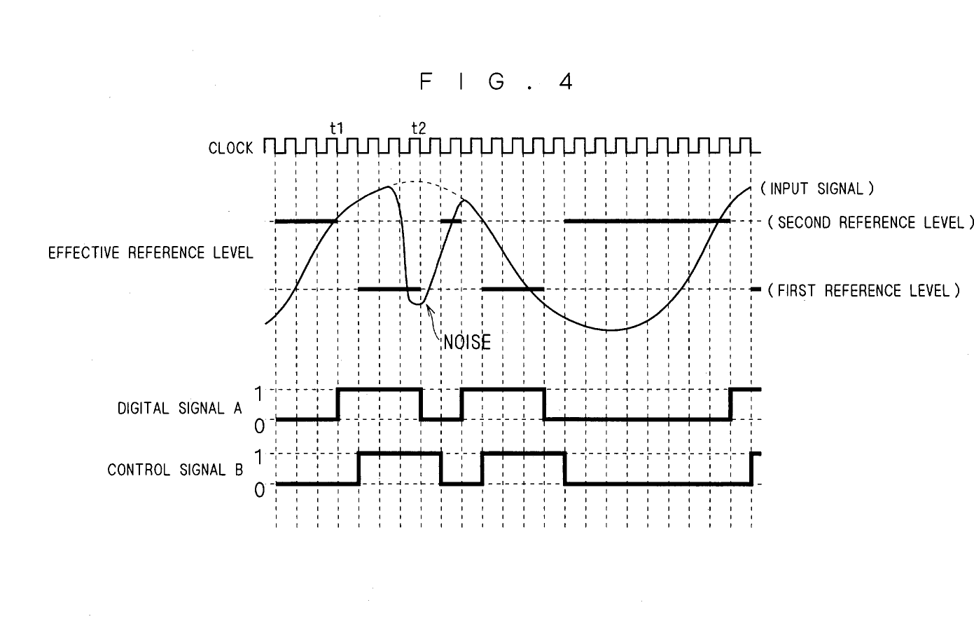

FIG. 3 is a view for illustrating an operation of the data slicer 100 according to the first preferred embodiment of the present invention. It is noted that the following description will be made on the assumption that a noise is superimposed on the input signal as illustrated in FIG. 3, for convenience's sake. Also, the following description will employ further assumptions that: the second reference level is higher than the first reference level; and the first selector circuit 4 switches the effective reference level between the first and second reference levels such that the first reference level is input as the effective reference level to the 0/1-determining circuit 2 when the control signal B has a value “1”, while the second reference level is input as the effective reference level to the 0/1-determining circuit 2 when the control signal B has a value “0”.

First, consider a situation where the level of the input signal is low so that the digital signal A has a value “0” and the control signal B has a value “0” (and in addition, the second reference level is employed as the effective reference level for the 0/1-determination carried out by the 0/1-determining circuit 2). In such a situation, when the level of the input signal increases to exceed the second reference level at an operation timing t1 as illustrated in FIG. 3, the 0/1-determining circuit 2 changes the value of the digital signal A to be output therefrom, from “0” to “1”. As a result, the value of the control signal B is changed from “0” to “1” at an operation timing t1+1 immediately after the operation timing t1 because the control part 3 includes the single latch circuit 5. Accordingly, the first selector circuit 4 inputs the first reference level lower than the second reference level to the 0/1-determining circuit 2, as the effective reference level. Hence, the first reference level is employed as the effective reference level for the 0/1-determination. Consequently, even if a noise is caused at an operation timing t2 as illustrated in FIG. 3, the level of the input signal will not fall below the effective reference level for the 0/1-determination, thereby to prevent an error in the 0/1-determination.

Next, consider that subsequently to the foregoing, the level of the input signal decreases to fall below the first reference level at an operation timing t3. In such a situation, the 0/1-determining circuit 2 changes the value of the digital signal A to be output therefrom, from “1” to “0”. As a result, the value of the control signal B is changed from “1” to “0” at an operation timing t3+1 immediately after the operation timing t3. Accordingly, the first selector circuit 4 inputs the second reference level higher than the first reference level to the 0/1-determining circuit 2, as the effective reference level. Hence, the second reference level is employed as the effective reference level for the 0/1-determination. Consequently, even if a noise is thereafter caused, it is possible to suppress errors in the 0/1-determination because the value of the input signal is unlikely to exceed the effective reference level for the 0/1-determination, illustration of which is omitted in the drawings.

As is made clear from the above-described operation of the data slicer 100, according to the first preferred embodiment, the effective reference level for the 0/1-determination in the data slicer 100 is changed with a hysteresis, thereby to suppress influences of a noise.

Thus, according to the first preferred embodiment, the effective reference level is switched between two levels based on the control signal B output from the control part 3 based on the digital signal A in the data slicer 100. As such, by altering an operation for generating the control signal B of the control part 3 in accordance with a type of an input signal, an amplitude of a noise superimposed on the input signal, or the like, it is also possible to suppress influences of a specific noise. In the following preferred embodiments, other examples of the operation for generating the control signal B of the control part 3 will be described.

Second Preferred Embodiment

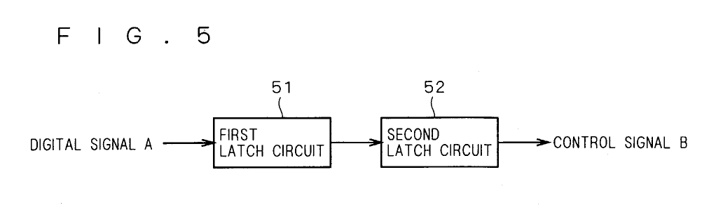

According to the first preferred embodiment, influences of a noise with a relatively small amplitude can be surely eliminated in the data slicer 100. However, the data slicer 100 may possibly suffer from erroneous determination in a situation where while the value of the digital signal A is “1”, a noise having such a great amplitude as to make the level of the input signal lower than the first reference level is caused, for example. In this situation, a plurality of pulses representing respective values may be output in one cycle during which a single pulse representing one value should be output if no noise is caused (hereinafter, referred to as a “pulse cycle”). FIG. 4 illustrates a possible operation of the data slicer 100 placed in the foregoing situation where a noise having a great amplitude is superimposed on the input signal in the first preferred embodiment. As is appreciated from the illustration FIG. 4, erroneous determination is made twice at operation timings t2 and t2+1 under influences of the noise.

To provide for the foregoing situation, according to a second preferred embodiment of the present invention, the data slicer 100 further includes, at an output stage thereof, a circuit for comparing respective numbers of values “1”s and “0”s contained in the digital signal A per pulse cycle, and choosing either a value “1” or “0”, whichever is numerically greater, to be used as a value of the digital signal A in the corresponding pulse cycle. Hereinafter, such a circuit will be referred to as a “majority-basis circuit”. For example, when a value of the digital signal A becomes “1” at five operation timings and becomes “0” at three operation timings in a single pulse cycle including eight operation timings, a value of the digital signal A in the corresponding pulse cycle is determined to be “1”. Accordingly, influences of unreliable values which may be contained in the digital signal A due to erroneous determination can be eliminated if the number of the unreliable values is small. Thus, inclusion of the majority-basis circuit, though erroneous determination may not be prevented at every operation timing, contributes to reduction of the number of times erroneous determination is made, to improve an accuracy of the 0/1-determination as a whole.

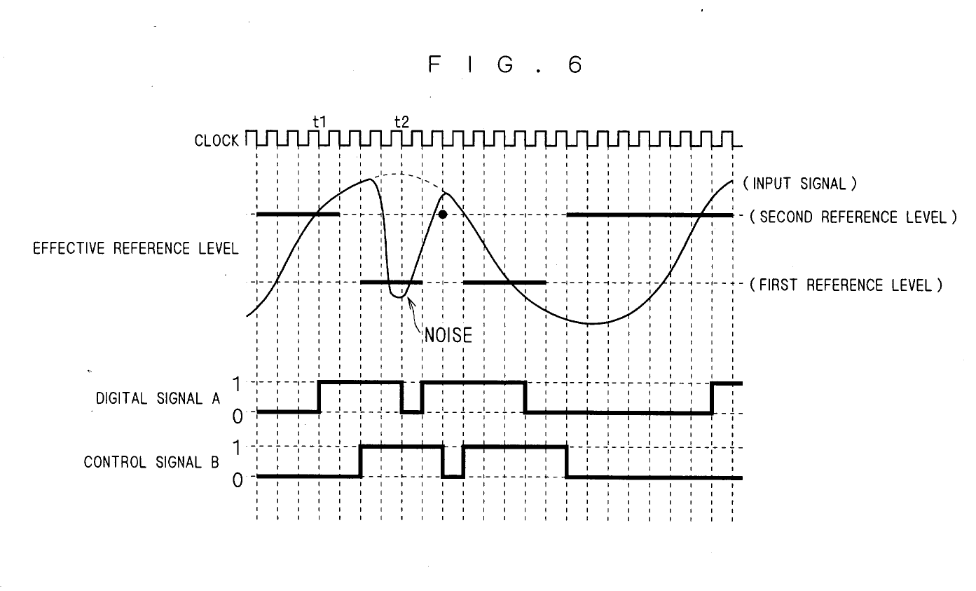

FIG. 5 is a view illustrating a structure of the control part 3 according to the second preferred embodiment. As illustrated therein, according to the second preferred embodiment, the control part 3 includes two latch circuits (a first latch circuit 51 and a second latch circuit 52) connected in series with each other. The first latch circuit 51 outputs a value of the digital signal A provided at an operation timing occurring in a preceding clock period. Then, the second latch circuit 52 outputs the value output from the first latch circuit 51, which corresponds to the value of the digital signal A provided at the operation timing occurring in the preceding clock period, as the control signal B. Accordingly, the control part 3 outputs a value of the digital signal A provided at an operation timing occurring two clock periods before a current clock period, as the control signal B. In other words, the control signal B is a signal obtained by delaying the digital signal A for two clock periods. Additionally, the structure of the data slicer 100 according to the second preferred embodiment is identical to that of the data slicer 100 illustrated in FIG. 1 in all the other respects than the control part 3, and thus detailed description thereof is omitted.

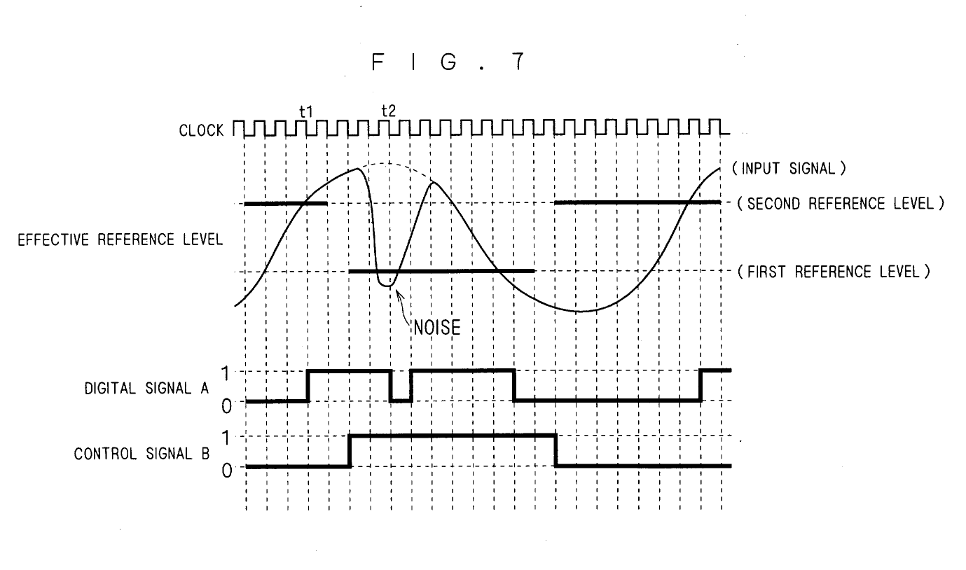

FIG. 6 illustrates an operation of the data slicer 100 according to the second preferred embodiment. A noise similar to that illustrated in FIG. 4 is superimposed on an input signal in FIG. 6. First, consider a situation where a level of the input signal increases to exceed the second reference level at an operation timing t1, at which the 0/1-determining circuit 2 changes a value of the digital signal A to be output, from “0” to “1”. As a result, a value of the control signal B is changed from “0” to “1” at an operation timing t1+2 occurring two clock periods after the operation timing t1 because the control part 3 includes the two latch circuits connected in series with each other. Accordingly, the first selector circuit 4 inputs the first reference level as the effective reference level to the 0/1-determining circuit 2. Hence, the first reference level is employed as the effective reference level for the 0/1-determination.

Subsequently to the foregoing, when the level of the input signal falls below the first reference level at an operation timing t2 under influences of the noise, the 0/1-determining circuit 2 changes the value of the digital signal A to be output, from “1” to “0”. This means that erroneous determination is made at the operation timing t2. In the operation as illustrated in FIG. 4, the effective reference level is then switched to the second reference level at a next operation timing t2+1, so that erroneous determination is further made after the level of the input signal exceeds the first reference level. In contrast, according to the second preferred embodiment, the first reference level is kept being employed as the effective reference level at the operation timing t2+1, so that the value of the digital signal A is returned back to “1”. This means that no erroneous determination is made at the operation timing t2+1. Then, the effective reference level is switched to the second reference level at an operation timing t2+2, at which the level of the input signal exceeds the second reference level, so that no erroneous determination is made. As described above, the second preferred embodiment makes it possible to reduce the number of times erroneous determination is made when a noise having a relatively great amplitude is caused, as compared with the first preferred embodiment. This contributes to improvement of an accuracy of the 0/1-determination in the data slicer 100.

Additionally, the second preferred embodiment has described that the control signal B is derived from a value of the digital signal A provided at an operation timing occurring two clock periods before a current clock period. However, the present invention should not be limited to such description. The control signal B may alternatively be derived from a value of the digital signal A provided at an operation timing occurring more than two clock periods before a current clock period.

Third Preferred Embodiment

According to a third preferred embodiment, the control part 3 functions to change the value of the control signal B only after the digital signal A keeps having the same value continuously over two or more clock periods. In other words, the control signal B is a signal not affected by a value of the digital signal A which is maintained for only a period(s) shorter than two clock periods.

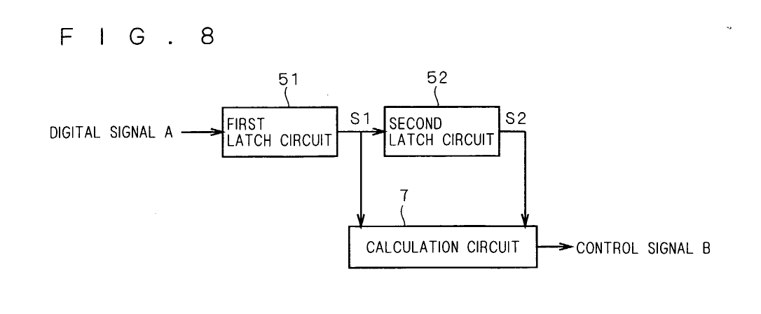

FIG. 7 is a view for illustrating an operation of the data slicer 100 according to the third preferred embodiment. A noise similar to that illustrated in FIG. 4 is superimposed on an input signal in FIG. 7. First, consider a situation where a level of the input signal increases to exceed the second reference level at an operation timing t1, at which the 0/1-determining circuit 2 changes a value of the digital signal A to be output, from “0” to “1”. As a result, a value of the control signal B is changed from “0” to “1” at an operation timing t1+2 occurring two clock periods after the operation timing t1 because the control part 3 changes the value of the control signal B only after the digital signal A keeps having the same value continuously over two clock periods. Accordingly, the first selector circuit 4 inputs the first reference level as the effective reference level to the 0/1-determining circuit 2. Hence, the first reference level is employed as the effective reference level for the 0/1-determination.

Subsequently to the foregoing, when the level of the input signal falls below the first reference level at an operation timing t2 under influences of the noise, the 0/1-determining circuit 2 changes the value of the digital signal A to be output, from “1” to “0”. This means that erroneous determination is made at the operation timing t2. Then, when the level of the input signal exceeds the first reference level at a next operation timing t2+1, the value of the digital signal A is returned back to “1”. Prior to the operation timing t2+1, the digital signal A has kept having the value “0” for only one clock period. Hence, the control part 3 does not change the value of the control signal B at that operation timing. As appreciated from comparison between FIGS. 4 and 7, the third preferred embodiment makes it possible to reduce the number of times erroneous determination is made when a noise having a relatively great amplitude is caused, as compared with the first preferred embodiment. This contributes to improvement of an accuracy of the 0/1-determination in the data slicer 100.

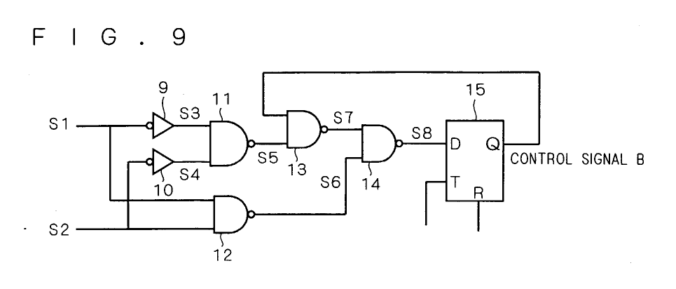

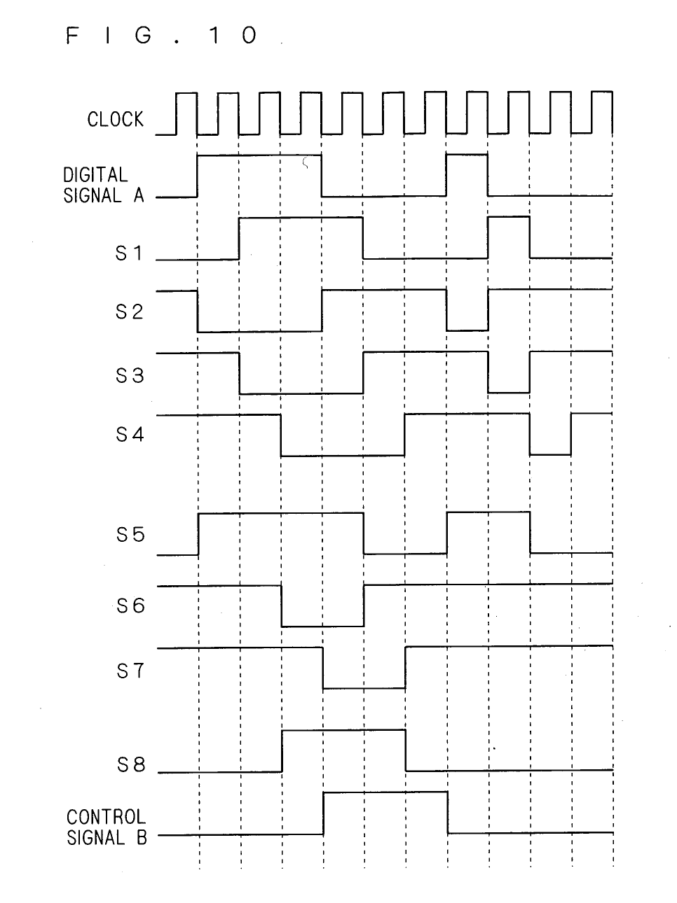

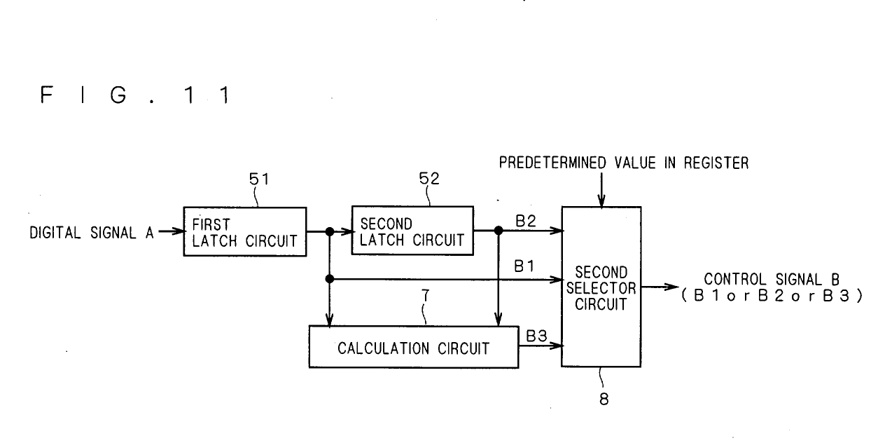

FIG. 8 is a view illustrating an exemplary structure of the control part 3 according to the third preferred embodiment. The control part 3 includes the first latch circuit 51, the second latch circuit 52 and a calculation circuit 7. An output signal S1 supplied from the first latch circuit 51 and an output signal S2 supplied from the second latch circuit 52 are input to the calculation circuit 7, which outputs the control signal B. FIG. 9 is a view illustrating an exemplary structure of the calculation circuit 7. FIG. 10 is a timing chart for illustrating an operation of the control part 3 including the calculation circuit 7 illustrated in FIG. 9. Signals S1 to S8 in FIG. 10 respectively correspond to signals denoted by the same reference numerals in FIGS. 8 and 9.

As illustrated in FIG. 9, the output signal S1 from the first latch circuit 51 is input to an inverter 9 and to a NAND circuit 12, and the output signal S2 from the second latch circuit 52 is input to an inverter 10 and to the NAND circuit 12. The inverters 9 and 10 supply the output signals S3 and S4, respectively, which are input to a NAND circuit 11. The NAND circuit 11 supplies the output signal S5 which is received by a NAND circuit 13 which also receives the control signal B output from a latch circuit 15. Further, the output signals S6 and S7 supplied from the NAND circuits 12 and 13, respectively, are input to the NAND circuit 14, which supplies the output signal S8 to be input to the latch circuit 15.

As appreciated from the timing chart of FIG. 10, after the digital signal A to be input to the control part 3 keeps having the same value continuously over two clock periods, the value of the control signal B is correspondingly changed. However, when the value of the digital signal A is changed from one value to the other value which is maintained for only one clock period, the value of the control signal B is not changed. Accordingly, the control signal B is not affected by a value of the digital signal A which is maintained for only a period(s) shorter than two clock periods. Because of arrangement illustrated in FIG. 9, it is possible to allow the control part 3 to generate the control signal B in the manner described above in the third preferred embodiment.

Additionally, the third preferred embodiment has described that the control part 3 changes the value of the control signal B only after the digital signal A keeps having the same value continuously over two or more clock periods. However, the present invention should not be limited to such description. The control part 3 may alternatively be configured such that it changes the value of the control signal B only after the digital signal A keeps having the same value continuously over a longer clock period.

Fourth Preferred Embodiment

FIG. 11 is a view illustrating a structure of the control part 3 of the data slicer 100 according to a fourth preferred embodiment. The control part 3 includes the first latch circuit 51, the second latch circuit 52, the calculation circuit 7 and a second selector circuit 8. The calculation circuit 7 is identical to that described in the third preferred embodiment. The second selector circuit 8 receives output signals B1, B2 and B3 supplied from the first latch circuit 51, the second latch circuit 52 and the calculation circuit 7, respectively. The second selector circuit 8 outputs one of the output signals B1, B2 and B3, as the control signal B. Which one of the signals B1, B2 and B3 is output from the second selector circuit 8 as the control signal B depends on a predetermined value stored in a register (not illustrated) included in the data slicer 100. A user is able to change a value of the control signal B by changing the predetermined value stored in the register.

It is clear that the signal B1 corresponds to the control signal B in the first preferred embodiment, the signal B2 corresponds to the control signal B in the second preferred embodiment, and the signal B3 corresponds to the control signal B in the third preferred embodiment. Thus, the second selector circuit 8 can switch the control signal B among: a signal derived from a value of the digital signal A provided at an operation timing occurring in a preceding clock period; a signal derived from a value of the digital signal A provided at an operation timing occurring two clock periods before a current clock period; and a signal derived from a value of the digital signal A which is maintained for two or more clock periods.

According to the fourth preferred embodiment, by switching a type of the control signal B generated by the control part 3, it is possible to eliminate a noise in accordance with a type of an input signal, an amplitude of a noise superimposed on the input signal or the like.

While the invention has been shown and described in detail, the foregoing description is in all aspects illustrative and not restrictive. It is therefore understood that numerous modifications and variations can be devised without departing from the scope of the invention.

What is claimed is:

1. A data slicer comprising:
a determining circuit for making determination of a level of an input signal relative to a predetermined reference level and outputting a digital signal in accordance with a result of said determination;
a control part for outputting a control signal based on said digital signal; and
a first selector circuit for changing said predetermined reference level based on said control signal.

2. The data slicer according to claim 1, wherein
said control part includes a single latch circuit for latching said digital signal and outputting said digital signal as said control signal.

3. The data slier according to claim 1, wherein
said control part includes a plurality of latch circuits connected in series with each other for latching said digital signal and outputting said digital signal as said control signal.

4. The data slicer according to claim 1, wherein
said control part outputs said digital signal as said control signal after said digital signal keeps having a same value continuously over a predetermine period of time.

5. The data slicer according to claim 1, wherein
said control part is capable of generating a first signal corresponding to a value of said digital signal provided at a preceding time and a second signal corresponding to a value of said digital signal provided at a time before said preceding time, and further includes a second selector circuit which is capable of switching a signal to be output as said control signal between said first and second signals.

6. The data slicer according to claim 5, wherein
said control part is capable of further generating a third signal which is not affected by a value of said digital signal which is maintained for only a period of time shorter than a predetermined period of time, and
said second selector circuit is capable of switching said signal to be output as said control signal among said first, second and third signals.
